(19) United States
(12) Patent Application Publication
(10) Pub. No.: US 2025/0294739 A1
(43) Pub. Date: Sep. 18, 2025

(54) METHOD OF MANUFACTURING SEMICONDUCTOR DEVICE

(71) Applicant: Kioxia Corporation, Tokyo (JP)

(72) Inventors: Wataru MATSUURA, Yokkaichi Mie (JP); Tatsunori ISOGAI, Yokkaichi Mie (JP); Masaki NOGUCHI, Yokkaichi Mie (JP)

(73) Assignee: Kioxia Corporation, Tokyo (JP)

(21) Appl. No.: 18/897,196

(22) Filed: Sep. 26, 2024

(30) Foreign Application Priority Data
Mar. 14, 2024 (JP) 2024-039583

(51) Int. Cl. H10B 41/35; H10B 43/35

(52) U.S. Cl. CPC H10B 41/35; H10B 43/35

(57) ABSTRACT

A method of manufacturing the semiconductor memory device includes forming a stacked film including a plurality of first layers containing an oxide and a plurality of second layers containing a nitride, a film thickness of each of the second layers being thicker than a film thickness of each of the first layers, the first layers and the second layers being alternately stacked one by one in a first direction; forming an opening penetrating the stacked film and extending in the first direction; and increasing the film thickness of each of the first layers and decreasing the film thickness of each of the second layers by an oxidation of the stacked film including the opening.

### CROSS-REFERENCE TO RELATED APPLICATION

This application is based upon and claims the benefit of priority from Japanese Patent Application No. 2024-039583, filed on Mar. 14, 2024, the entire contents of which are incorporated herein by reference.

### FIELD

Embodiments described herein relate generally to a method of manufacturing a semiconductor device.

### BACKGROUND

Large-capacity nonvolatile memories have been developed. This large-capacity nonvolatile memory is capable of low-voltage and low-current operation, high-speed switching, and miniaturization and high integration of memory cells.

Many metallic wires called bit lines and word lines are arranged in a memory cell array of the large-capacity nonvolatile memory. A voltage is applied to the memory cell connected to the bit line and the word line, and data is written to one memory cell corresponding to the bit line and the word line. The semiconductor memory device has been proposed in which memory cells are three-dimensionally arranged with stacked films in which a conductive layer serving as the word line and an insulating layer are alternately stacked.

### BRIEF DESCRIPTION OF THE DRAWINGS

FIG. 1 is a block diagram of the semiconductor memory device according to an embodiment.

FIG. 2 is an equivalent circuit diagram of the semiconductor memory device of the embodiment.

FIG. 3 is a schematic cross-sectional view of the main part of the semiconductor memory device of the embodiment.

FIG. 4 is a schematic cross-sectional view showing a process for manufacturing the semiconductor memory device of the embodiment.

FIG. 5 is a schematic cross-sectional view showing the process for manufacturing the semiconductor memory device of the embodiment.

FIG. 6 is a schematic cross-sectional view showing the process for manufacturing the semiconductor memory device of the embodiment.

FIG. 7 is a schematic cross-sectional view showing the process for manufacturing the semiconductor memory device of the embodiment.

FIG. 8 is a schematic cross-sectional view showing the modification of the process for manufacturing the semiconductor memory device of the embodiment.

FIG. 9 is a schematic cross-sectional view showing the modification of the process for manufacturing the semiconductor memory device of the embodiment.

FIG. 10 is a schematic cross-sectional view showing the modification of the process for manufacturing the semiconductor memory device of the embodiment.

### DETAILED DESCRIPTION

Hereinafter, embodiments will be described with reference to the diagrams. In addition, in the diagrams, the same or similar elements are denoted by the same or similar reference numerals.

In the present specification, to show the positional relationship of the components and the like, the upward direction of the drawings is described as “up”, and the downward direction of the drawings is described as “down”. In the present specification, the terms “up” and “down” do not necessarily indicate the relationship with the direction of gravity.

### Embodiment

A method of manufacturing the semiconductor memory device includes forming a stacked film including a plurality of first layers containing an oxide and a plurality of second layers containing a nitride, a film thickness of each of the second layers being thicker than a film thickness of each of the first layers, the first layers and the second layers being alternately stacked one by one in a first direction; forming an opening penetrating the stacked film and extending in the first direction; and increasing the film thickness of each of the first layers and decreasing the film thickness of each of the second layers by an oxidation of the stacked film including the opening.

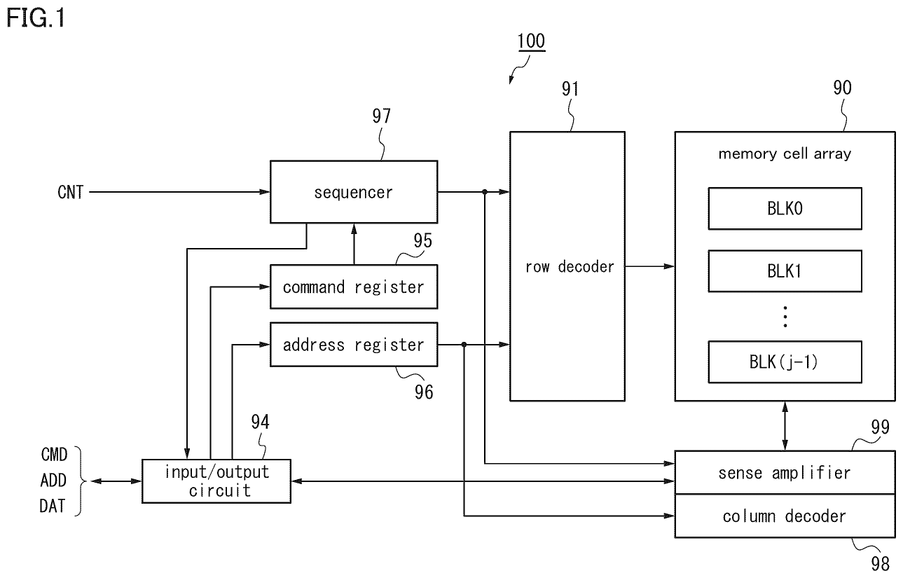

The entire configuration of the semiconductor memory device 100 will be described. The semiconductor memory device 100 according to the present embodiment is a NAND flash memory capable of storing data non-volatilely. FIG. 1 is a block diagram of the semiconductor memory device according to the embodiment.

The semiconductor memory device 100 includes a memory cell array 90, a row decoder 91, a column decoder 98, a sense amplifier 99, an input/output circuit 94, a command register 95, an address register 96, and a sequencer (control circuitry) 97.

The memory cell array 90 includes j blocks BLK0-BLK(j−1). j is an integer of 1 or more. Each of the plurality of blocks BLK includes a plurality of memory cell transistors. The memory cell transistor includes an electrically rewritable memory cell. The memory cell array 90 includes a plurality of bit lines, a plurality of word lines, and a source line, etc. to control the voltage applied to the memory cell transistor. A specific configuration of the blocking BLK will be described later.

The row decoder 91 receives a row address from the address register 96 and decodes the row address. The row decoder 91 performs a selection operation of the word lines and so on based on the decoded row address. The row decoder 91 transmits a plurality of voltages required for a write operation, a read operation, and an erase operation to the memory cell array 90.

The column decoder 98 receives the column address from the address register 96 and decodes this column address. The column decoder 98 performs a selection operation of the bit lines based on the decoded column address.

During the read operation, the sense amplifier 99 detects and amplifies the data read from the memory cell transistor to the bit line. During the write operation, the sense amplifier 99 transfers the write data to the bit line.

The input/output circuit 94 is connected to an external device (host device) via a plurality of input/output lines (DQ lines). The input/output circuit 94 receives the command CMD and the address ADD from the external device. The command CMD received by the input/output circuit 94 is sent to the command register 95. The address ADD received by the input/output circuit 94 is sent to an address register 96. The input/output circuit 94 transmits and receives DAT to and from the external device.

The sequencer 97 receives a control signal CNT from the external device. The control signal CNT includes the chip enable signal CEn, the command latch enable signal CLE, the address latch enable signal ALE, the write enable signal WEn, and the read enable signal REn. The “n” appended to the signal name indicates active low. The sequencer 97 controls the operation of the entire semiconductor memory device 100 based on the command CMD and the control signal CNT held in the command register 95.

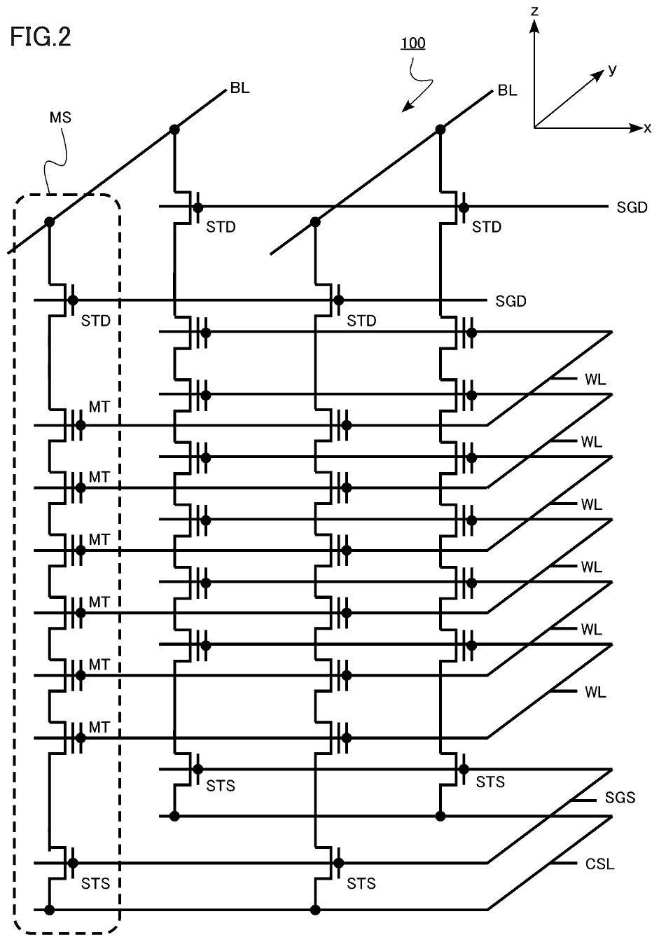

FIG. 2 is the equivalent circuit diagram of the semiconductor memory device 100 of the present embodiment.

As shown in FIG. 2, the semiconductor memory device 100 includes a plurality of word lines WL, a common source line CSL, a source selection gate line SGS, a plurality of drain select gate lines SGD, a plurality of bit lines BL, and a plurality of memory strings MS.

The memory string MS has a source selection transistor STS, a plurality of memory cell transistors MT, and a drain selection transistor STD connected in series between the common source line CSL and the bit line BL.

The number of word lines WL, the number of bit lines BL, the number of memory strings MS, and the number of drain select gate lines SGD are not limited to those of FIG. 2.

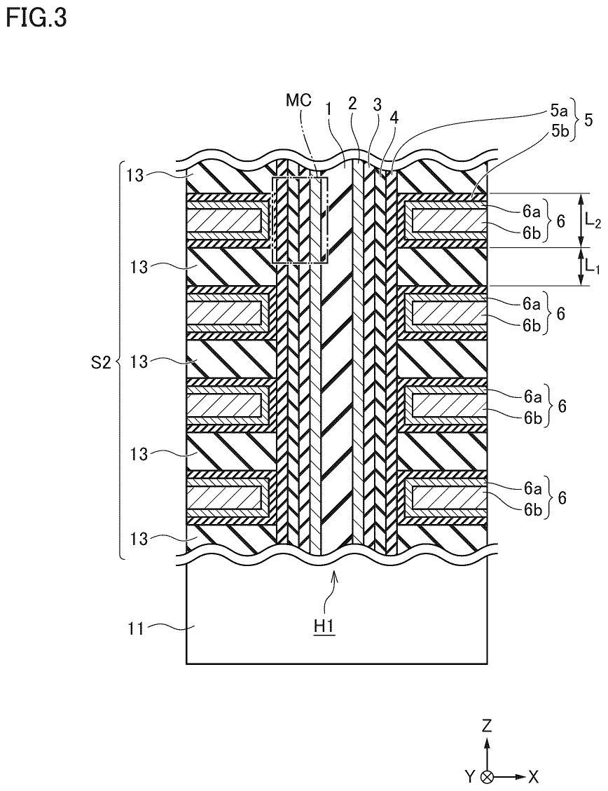

FIG. 3 is the schematic cross-sectional view of the main part of the semiconductor memory device of the embodiment.

A substrate 11 is, for example, a semiconductor layer containing single-crystal silicon. As the substrate 11, for example, a semiconductor wafer or a SOI wafer can be used.

Here, an X direction, a Y direction that intersects perpendicularly with the X direction, and a Z direction that intersects perpendicularly with the X direction and the Y direction are defined. The substrate 11 is provided parallel to the XY surface. The Z direction is an exemplary the first direction.

On the substrate 11, a plurality of first layers 13 including an oxide and a plurality of conductive layers 6b are alternately stacked one by one in the Z direction. Thus, a stacked film S2 is provided on the substrate 11. Here, the oxide is, for example, a silicon oxide.

The memory pillar H1 penetrates the stacked film S2 in the Z direction. In the memory pillar H1, a core insulating film 1, a channel semiconductor layer 2, a tunnel insulating film 3, a charge storage film 4, and an insulating film 5a are provided.

The core insulating film 1 is provided in the memory pillar H1. The core insulating film 1 contains, for example, a silicon oxide.

The channel semiconductor layer 2 is provided around the core insulating film 1 in the memory pillar H1. The channel semiconductor layer 2 functions as a channel of the memory pillar H1. The channel semiconductor layer 2 is a pillar containing a semiconducting material such as polysilicon.

The tunnel insulating film 3 is provided around the channel semiconductor layer 2. The tunnel insulating film 3 is an insulating film that allows a current to flow by applying a predetermined voltage. The tunnel insulating film 3 contains, for example, a silicon oxynitride.

The charge storage film 4 is provided around the tunnel insulating film 3. The charge storage film 4 is a film containing a material capable of storing electric charges. The charge storage film 4 contains, for example, a silicon nitride.

The insulating film 5a is provided around the charge storage film 4. The insulating film 5a contains, for example, a silicon oxide.

The insulating film 5b, the barrier metal layer 6a, and the conductive layer 6b are provided between the first layers 13 adjacent to each other.

The insulating film 5b is provided on the lower surface of the first layer 13 adjacent to the upper side, the upper surface of the first layer 13 adjacent to the lower side, and the side surface of the insulating film 5a. The insulating film 5b includes, for example, a metallic insulating material such as aluminum oxide.

The barrier metal layer 6a is provided on the lower surface of the upper insulating film 5b, the upper surface of the lower insulating film 5b, and the side surface of the insulating film 5b provided on the side surface of the insulating film 5a. The barrier metal layer 6a contains, for example, titanium nitride.

The conductive layer 6b is provided in the barrier metal layer 6a. The conductive layer 6b contains, for example, W (tungsten). The conductive layer 6b corresponds to the word line WL.

The film thickness L₁ of the first layer 13 in the Z direction is, for example, 17 nm. The distance L₂ between the first layers 13 adjacent to each other in the Z direction is, for example, 22 nm. Note that the film thickness L₁ of the first layer 13 and the distance L₂ between the first layers 13 adjacent to each other in the Z direction are not limited to the above described one.

A memory cell MC is provided at a part of the memory pillar H1 facing the conductive layer 6b. A plurality of memory cells MC provided in one memory pillar H1 are included in one memory string MS. Each memory cell MC contains a memory cell transistor MT.

Note that in FIG. 3, one memory string MS out of the memory string MS shown in FIG. 2 is shown. The semiconductor memory device 100 includes a plurality of memory pillars H1.

Between the stacked film S2 and the substrate 11, for example, a common source line CSL (not shown), a source selection gate line SGS, and a plurality of source selection transistors STS are provided.

On the stacked film S2, for example, a plurality of drain select gate lines SGD, a plurality of bit lines BL, and a plurality of drain selection transistors STD (not shown) are provided.

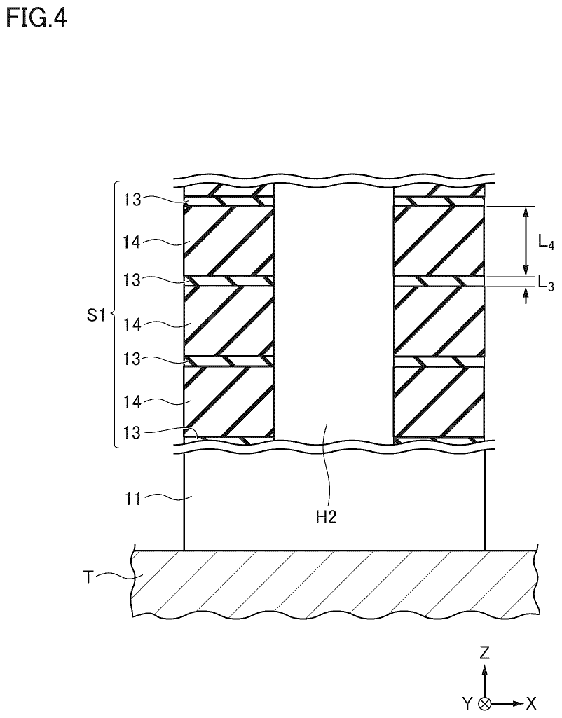

FIG. 4 to FIG. 7 are schematic cross-sectional views showing the process for manufacturing the semiconductor memory device of the embodiment.

As shown in FIG. 4, the common source line CSL (not shown), the source select gate line SGS, and a plurality of source selection transistors STS are formed on the substrate 11. Note that the substrate 11 is placed on the stage T in a reaction chamber in which the semiconductor memory device is manufactured, for example.

Next, a plurality of the first layers 13 including the oxide and a plurality of the second layers 14 including the nitride are formed by alternating layers one by one in the Z direction, for example, by CVD (Chemical Vapor Deposition) method. Thus, the stacked film S1 is formed. The oxide is, for example, silicon oxide. The nitride is, for example, silicon nitride. In FIG. 4, the film thickness L₃ of the first layer 13 in the Z direction is, for example, 5.6 nm. The film thickness L₄ of the second layer 14 in the Z direction is, for example, 30.6 nm. Thus, the film thickness L₄ of the second layer 14 is thicker than the film thickness L₃ of the first layer. Next, an opening H2 (through hole) penetrating the stacked film S1 in the Z direction and extending in the Z direction is formed by, for example, RIE (Reactive Ion Etching) method (FIG. 4). Here, when the opening H2 is formed, the temperature of the stage T on which the stacked film S1 is placed is preferably 70° C. or less.

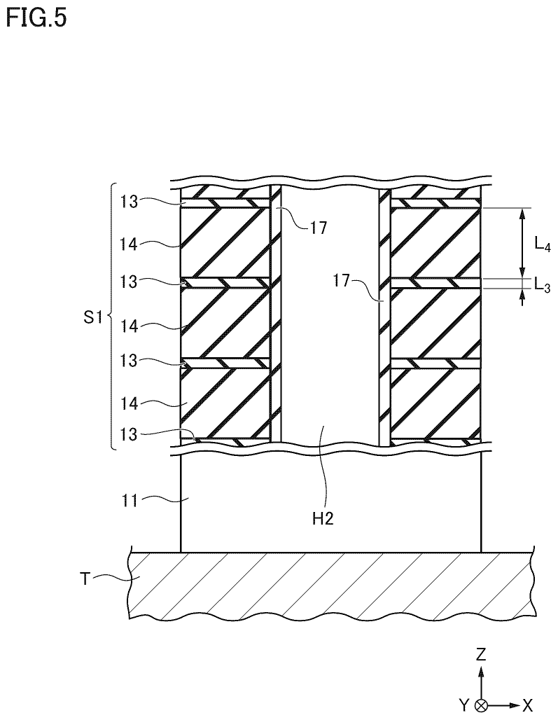

Next, as shown in FIG. 5, by, for example, ALD (Atomic Layer Deposition) method, a fifth layer 17 (exemplary a third layer) containing nitride, for example, silicon nitride, is formed on the side surfaces of the first layers 13 and the side surfaces of the second layers 14 exposed in the opening H2. The fifth layer 17 has, for example, a cylindrical shape including the opening H2. In FIG. 5, the fifth layer 17 may be formed on the bottom surface of the opening H2 although it is formed on the side surface of the opening H2.

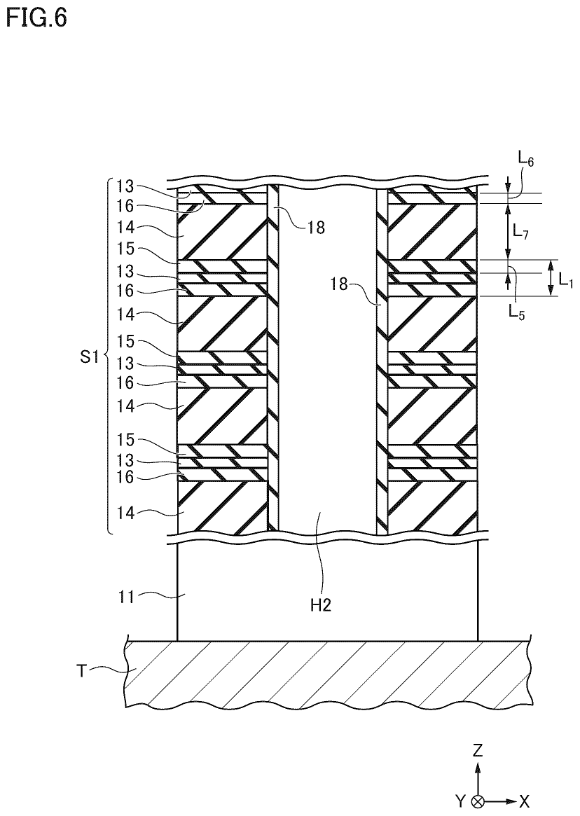

Next, as shown in FIG. 6, the stacked film S1 including the opening H2 is oxidized. Here, a part of the second layer 14 including the lower surface of the second layer 14 is oxidized to form a third layer 15 including the oxide between the second layer 14 and the first layer 13 below the second layer 14 and adjacent to the second layer 14. In addition, a part of the second layer 14 including the upper surface of the second layer 14 is oxidized to form a fourth layer 16 including the oxide between the second layer 14 and the first layer 13 above the second layer 14 and adjacent to the second layer 14. Further, by oxidizing the stacked film S1 including the opening H2, the fifth layer 17 is oxidized to form a sixth layer 18 containing the oxide (an exemplary the fourth layer). (Hereinafter, the oxidation step shown in FIG. 6 may be referred to as “oxidation”).

As a result, the film thickness of the second layers 14 containing the nitride is reduced by oxidization, respectively.

Here, by oxidizing the stacked film S1 including the opening H2, as described above, the third layer 15 containing the oxide and the fourth layer 16 containing the oxide are formed. Here, considering that each of the first layers 13 includes the fourth layer 16 formed below each of the first layers 13 and the third layer 15 formed on each of the first layers 13, the film thicknesses of the first layers 13 including the oxide may be considered to have increased by the film thickness of the third layer 15 and the film thickness of the fourth layer 16, respectively.

In FIG. 3, the respective first layer 13, the fourth layer 16 formed below the respective first layer 13, and the third layer 15 formed on the respective first layer 13 in FIG. 6 are collectively illustrated as “the first layer 13”.

In other words, the stacked film S1 including the opening H2 is oxidized to oxidize the part of the second layer 14 in contact with the first layer 13. As a result, the film thicknesses of the first layers 13 including oxide are increased by the film thickness of the third layer 15 and the film thickness of the fourth layer 16, respectively. In addition, the film thicknesses of the second layers 14 including nitride are respectively decreased.

The process of increasing the film thicknesses of the first layers 13 and the process of decreasing the film thicknesses of the second layers 14 are not limited to those described above.

Here, the film thickness 15 of the third layer 15 in the Z direction is, for example, 5.7 nm. The film thickness L₆ of the fourth layer 16 in the Z direction is, for example, 5.7 nm. Also, after oxidizing in the Z direction, the second layer 14 has a lower film thickness Ly than the film thickness L₄ shown in FIG. 4 and FIG. 5. The film thickness L₇ of the second layer 14 in the Z direction is, for example, 22 nm.

The sum of the film thickness L₅ of the third layer 15 in the Z direction and the film thickness L₆ of the fourth layer 16 in the Z direction and the film thickness L₇ of the second layer 14 in the Z direction (L₅+L₆+L₇) shown in FIG. 6 is thicker than the film thickness L₄ of the second layer 14 in the Z direction shown in FIG. 4 and FIG. 5. This is because the silicon nitride is oxidized to the silicon oxide, thereby increasing the volume. Thus, the difference (L₁₀−L₁₁) between the film thickness (L₁₀) of the stacked film S1 after the oxidation and the film thickness (L₁₁) of the stacked film S1 before the oxidation is larger than 0.1 μm. For example, in the case of the stacked film S1 formed by repeating the first layer 13 and the second layer 14 320 times, the difference (L₁₀−L₁₁) of such film thickness is about 2 μm.

In another embodiment, the film thickness L₃ of the first layer 13 in the Z direction before oxidation is, for example, 2.3 nm. Further, the film thickness L₄ of the second layer 14 in the Z direction before oxidation is, for example, 30.6 nm. Further, the film thickness L₅ of the third layer 15 in the Z direction after oxidation is, for example, 7.35 nm, respectively. Further, the film thickness L₆ of the fourth layer 16 in the Z direction after oxidation is, for example, 7.35 nm, respectively. Further, the film thickness Ly of the second layer 14 in the Z direction after oxidation is, for example, 22 nm, respectively.

In another embodiment, the film thickness L₃ of the first layer 13 in the Z direction before oxidation is, for example, 4.4 nm, respectively. Further, the film thickness L₄ of the second layer 14 in the Z direction before oxidation is, for example, 30.6 nm, respectively. Further, the film thickness L₅ of the third layer 15 in the Z direction after oxidation is, for example, 6.3 nm, respectively. Further, the film thickness Le of the fourth layer 16 in the Z direction after oxidation is, for example, 6.3 nm, respectively. Further, the film thickness L₇ of the second layer 14 in the Z direction after oxidation is, for example, 22 nm, respectively.

In the present embodiment, the film thickness L₃ of the first layer 13 in the Z direction before oxidation is, for example, preferably 0.3 nm or more and 10 nm or less, and the film thickness L₄ of the second layer 14 in the Z direction before oxidation is, for example, preferably 25 nm or more and 45 nm or less. The film thickness L₃ of the first layer 13 in the Z direction before oxidation has a ratio of 0.5% to 30% of the sum of the film thickness of L₃ of the first layer 13 and the film thickness L₄ of the second layer 14 in the Z direction before oxidation.

In the present embodiment, the film thickness L₁ (L₃+L₅+L₆) of the first layer 13 in the Z direction after oxidation is increased to a ratio of 35% to 45% with respect to the sum of the film thickness L₁ of the first layer 13 and the film thickness L₇ of the second layer 14 in the Z direction after oxidation.

The stacked film S1 including the opening H2 is preferably oxidized by the wet oxidation (e.g., H₂O annealing) under high-pressure conditions. The wet oxidation is performed by, for example, using hydrogen gas and oxygen gas, and supplying water vapor (H₂O) generated by a combustion reaction of hydrogen gas and oxygen gas into a reaction chamber in which the semiconductor memory device is manufactured.

Here, the partial pressure of the water vapor (H₂O) in the reactor chamber is preferably 10 atmospheres or more, and may be 20 atmospheres or more. The temperature in the reaction chamber is preferably 400° C. or more. The time for oxidizing the stacked film S1 is preferably, for example, 10 minutes or more and 1 hour or less, and is, for example, about 30 minutes.

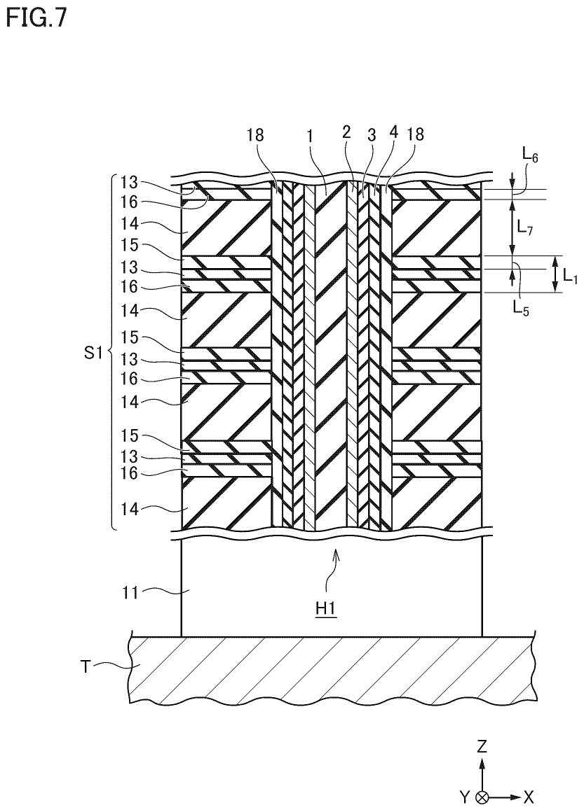

Next, a part of the charge storage film 4, the tunnel insulating film 3, and the channel semiconductor layer 2 are sequentially formed in the opening H2 by, e.g., ALD (Atomic Layer Deposition). The sixth layer 18 is used as the insulating film 5a shown in FIG. 3. Next, a part of the sixth layer 18, the charge storage film 4, the tunnel insulating film 3, and the channel semiconductor layer 2 are removed from the bottom of the opening H2 by, for example, etching. Next, the remainder of the channel semiconductor layer 2 and the core insulating film 1 are sequentially formed in the opening H2 by, for example, ALD (Atomic Layer Deposition). In the opening H2, the sixth layer 18, the charge storage film 4, the tunnel insulating film 3, the channel semiconductor layer 2, and the core insulating film 1 are formed in this order (FIG. 7).

Next, a slit (not shown) is formed in the stacked film S1. Next, a chemical solution such as phosphoric acid is supplied using the slit, and the plurality of second layers 14 is removed. Next, the insulating film 5b, the barrier metal layer 6a, and the conductive layer 6b are sequentially formed on the part from which the plurality of the second layers 14 has been removed. Thus, the stacked film S2 is formed.

Next, a plurality of drain select gate lines SGD, a plurality of bit lines BL, and a plurality of drain selection transistors STD (not shown) are formed on the stacked film S2. As a result, the semiconductor memory device 100 of the embodiment is obtained.

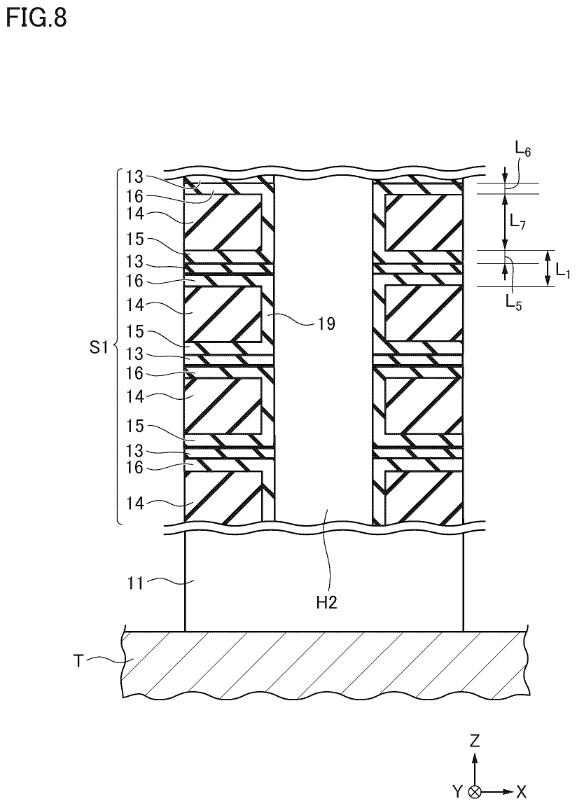

FIG. 8 to FIG. 10 are schematic cross-sectional views that illustrate a modification of the method of manufacturing the semiconductor memory device according to the embodiment.

The common source line CSL, the source select gate line SGS, and the plurality of source selection transistors STS (not shown) are formed on the substrate 11, the stacked film S1 is formed, and the opening H2 (through hole) (FIG. 4) is formed similarly as those of the method of manufacturing the semiconductor memory device according to the embodiment.

Next, the stacked film S2 including the opening H2 is oxidized without forming the fifth layer 17. Here, the third layer 15 and the fourth layer 16 are formed, and each of the side surfaces of the second layers 14 is oxidized to form the seventh layer 19 containing the oxide (e.g., Si oxide).

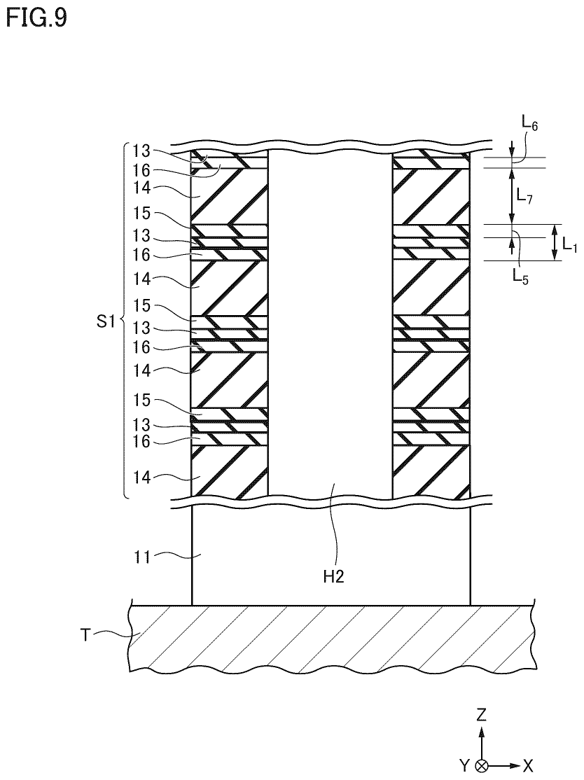

Next, the seventh layer 19, a part of the first layer 13, a part of the third layer 15, and a part of the fourth layer 16 are removed using, for example, a RIE method. This exposes the side surface of the non-oxidized second layer 14 (FIG. 9).

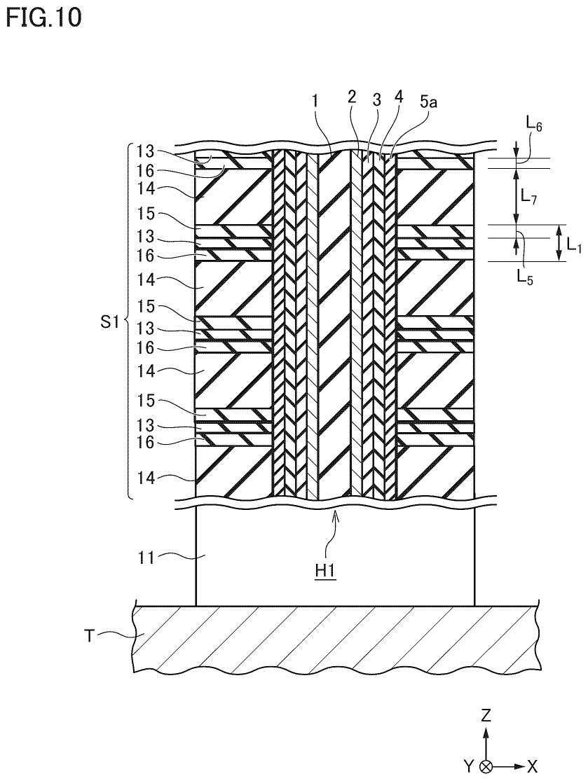

Then, in the opening H2, the insulating film 5a, the charge storage film 4, the tunnel insulating film 3, and the channel semiconductor layer 2 are sequentially formed by, for example, ALD (Atomic Layer Deposition) method. Then, from the bottom of the opening H2, a portion of the insulating film 5a, the charge storage film 4, the tunnel insulating film 3 and the channel semiconductor layer 2 are removed, for example, by etching. Next, the remainder of the channel semiconductor layer 2 and the core insulating film 1 are sequentially formed in the opening H2 by, for example, ALD (Atomic Layer Deposition). In the opening H2, the insulating film 5a, the charge storage film 4, the tunnel insulating film 3, the channel semiconductor layer 2, and the core insulating film 1 are formed in this order (FIG. 10). The subsequent manufacturing steps are the same as those of the semiconductor manufacturing apparatus of the embodiment.

Next, the operation and advantages of the manufacturing method of the semiconductor memory device according to the embodiment will be described.

As the stacked film S1 becomes more highly stacked, the depth of the opening H2 in the Z direction to be formed increases. Therefore, it is difficult to form the opening H2.

When the opening H2 is formed, the first layer 13 and the second layer 14 are alternately processed. Therefore, conditions for optimum manufacturing vary depending on, for example, the film thickness of the first layer 13, the film thickness of the second layer 14, and the ratio of the film thickness of the first layer 13 to the film thickness of the second layer 14. This was also a factor that made it difficult to form the opening H2.

Therefore, the method of manufacturing the semiconductor memory device of the embodiment includes forming a stacked film including a plurality of first layers containing an oxide and a plurality of second layers containing a nitride, a film thickness of each of the second layers being thicker than a film thickness of each of the first layers, the first layers and the second layers being alternately stacked one by one in a first direction; forming an opening penetrating the stacked film and extending in the first direction; and increasing the film thickness of each of the first layers and decreasing the film thickness of each of the second layers by an oxidation of the stacked film including the opening.

When a portion of the second layer 14 containing the nitride is oxidized to form a layer containing the oxide, the film thickness of the portion of the second layer 14 that is oxidized to the oxide is increased relative to the film thickness prior to being oxidized. This is because the volume of the silicon oxide per silicon Si atom is larger than the volume of the silicon nitride per Si atom.

Then, when the opening H2 is formed before oxidizing the stacked film S1, the opening H2 can be easily formed because the film thickness of the entire stacked film S1 in the Z direction is thinner. Further, by oxidizing the stacked film S1 after forming the opening H2, the film thickness of the first layer 13 containing the oxide can be increased. For this reason, for example, it is possible to easily suppress the breakdown between the adjacent memory cells MC and secure the isolation between the adjacent word lines WL.

When the opening H2 is formed, the film thickness of the second layer 14 containing the nitride can be made thicker. For this reason, it is possible to easily form the opening H2 by making the processing conditions more suitable for processing the second layer 14 than for processing the first layer 13.

The stacked film S1 is preferably oxidized by the wet oxidation under high-pressure conditions. Normally, it is difficult to form the first layer 13 containing the oxide by oxidation of the second layer 14 containing the nitride unless a highly reactive manufacturing process such as radical oxidation is used. However, there is a problem that the oxidative power is lowered due to deactivation of radicals or the like. On the other hand, when the wet oxidation is used under high pressure conditions, the oxidative power is not reduced due to deactivation of radicals or the like. Therefore, for example, an increase in the oxidation rate and an increase in the coverage of the formed oxide layers can be expected.

Here, the partial pressure of the water vapor (H₂O) in the reactor chamber is preferably 10 atmospheres or more in order to advance the wet oxidation. In addition, the temperature in the reaction chamber is preferably 400° C. or more to proceed with the wet oxidation.

It is preferable that a temperature of the stage T on which the stacked film S1 is placed is 70° C. or less when forming the processing portion. The processing rate of the second layer 14 containing the nitride is particularly increased when the temperature of the stage T is 70° C. or less. Thus, the opening H2 can be formed faster.

According to the method of manufacturing the semiconductor device according to the present embodiment, it is possible to provide the semiconductor memory device manufacturing method capable of easily manufacturing the semiconductor memory device.

While certain embodiments have been described, these embodiments have been presented by way of example only, and are not intended to limit the scope of the inventions. Indeed, the method of manufacturing the semiconductor device described herein may be embodied in a variety of other forms; furthermore, various omissions, substitutions and changes in the form of the devices and methods described herein may be made without departing from the spirit of the inventions, for manufacturing Indeed, the semiconductor memory device The accompanying claims and their equivalents are intended to cover such forms or modifications as would fall within the scope and spirit of the inventions.

What is claimed is:

1. A method of manufacturing a semiconductor memory device, comprising:
forming a stacked film including a plurality of first layers containing an oxide and a plurality of second layers containing a nitride, a film thickness of each of the second layers being thicker than a film thickness of each of the first layers, the first layers and the second layers being alternately stacked one by one in a first direction;
forming an opening penetrating the stacked film and extending in the first direction; and
increasing the film thickness of each of the first layers and decreasing the film thickness of each of the second layers by an oxidation of the stacked film including the opening.

2. The method of manufacturing the semiconductor memory device according to claim 1,
wherein the oxidation is a wet oxidation.

3. The method of manufacturing the semiconductor memory device according to claim 2,
wherein the wet oxidation is performed by using hydrogen gas and oxygen gas.

4. The method of manufacturing the semiconductor memory device according to claim 2,
wherein, when the wet oxidation is performed, a partial pressure of the water vapor (H₂O) in a reactor chamber in which the semiconductor memory device is manufactured is 10 atmospheres or more.

5. The method of manufacturing the semiconductor memory device according to claim 2,
wherein, when the wet oxidation is performed, a temperature in a reaction chamber in which the semiconductor memory device is manufactured is 400° C. or more.

6. The method of manufacturing the semiconductor memory device according to claim 1,
wherein, when the opening penetrating the stacked film and extending in the first direction is formed, a temperature of a stage on which the stacked film is placed is 70° C. or less.

7. The method of manufacturing the semiconductor memory device according to claim 1,
wherein a difference between the film thickness of the stacked film after the oxidation and the film thickness of the stacked film before the oxidation is larger than 0.1 μm.

8. The method of manufacturing the semiconductor memory device according to claim 1,
wherein, before the oxidation, the film thickness of one of the first layers in the first direction is 0.3 nm or more and 10 nm or less, and the film thickness of the second layer in the first direction and in contact with the one of the first layers is 25 nm or more and 45 nm or less.

9. The method of manufacturing the semiconductor memory device according to claim 1,
wherein, after the oxidation, the film thickness of one of the first layers is 35% or more and 45% or less with respect to a total film thickness of one of the first layers and the second layer in contact with the one of the first layers.

10. The method of manufacturing the semiconductor memory device according to claim 1, further comprising:
after forming the opening penetrating the stacked film and extending in the first direction and before the oxidation of the stacked film including the opening, forming a third layer containing a nitride on side surfaces of the first layers and side surfaces of the second layers exposed in the opening; and
when the oxidation of the stacked film including the opening is performed, oxidizing the third layer.

11. The method of manufacturing the semiconductor memory device according to claim 1, further comprising:
when the oxidation of the stacked film including the opening is performed,
forming a third layer between one of the second layers and one of the first layers below the one of the second layers and adjacent to the one of the second layers,
forming a fourth layer between one of the second layers and one of the first layers above the one of the second layers and adjacent to the one of the second layers; and
decreasing the film thickness of each of the second layers.

12. The method of manufacturing the semiconductor memory device according to claim 1,
wherein each of the first layers has a first film thickness,
wherein the third layer has a second film thickness,
wherein the fourth layer has a third film thickness, and
wherein the film thickness of the first layer after performing the oxidation of the stacked film including the opening is a sum of the first film thickness before the oxidation, the second film thickness and the third film thickness.

13. A method of manufacturing a semiconductor memory device, comprising:
forming a stacked film including a plurality of first layers containing an oxide and a plurality of second layers containing a nitride, a second film thickness of each of the second layers being thicker than a first film thickness of each of the first layers, the first layers and the second layers being alternately stacked one by one in a first direction;
forming an opening penetrating the stacked film and extending in the first direction; and
increasing the first film thickness of each of the first layers to the third film thickness and decreasing the second film thickness of each of the second layers to the fourth film thickness by an oxidation of the stacked film including the opening, the second film thickness being thicker than the first film thickness, and the fourth film thickness being thinner than the third film thickness.

14. The method of manufacturing the semiconductor memory device according to claim 13, further comprising:
when the oxidation of the stacked film including the opening is performed,
forming a third layer between one of the second layers and one of the first layers below the one of the second layers and adjacent to the one of the second layers,
forming a fourth layer between one of the second layers and one of the first layers above the one of the second layers and adjacent to the one of the second layers; and
decreasing the film thickness of each of the second layers to the fourth film thickness.

15. The method of manufacturing the semiconductor memory device according to claim 14,
wherein the third layer has a fifth film thickness,
wherein the fourth layer has a sixth film thickness, and
wherein the third film thickness is a sum of the first film thickness, the fifth film thickness and the sixth film thickness.

16. The method of manufacturing the semiconductor memory device according to claim 13,
wherein the oxidation is a wet oxidation, and
wherein the wet oxidation is performed by using hydrogen gas and oxygen gas.

17. The method of manufacturing the semiconductor memory device according to claim 16,
wherein, when the wet oxidation is performed, a partial pressure of the water vapor (H₂O) in a reactor chamber in which the semiconductor memory device is manufactured is 10 atmospheres or more,
wherein, when the wet oxidation is performed, a temperature in a reaction chamber in which the semiconductor memory device is manufactured is 400° C. or more, and
wherein, when the opening penetrating the stacked film and extending in the first direction is formed, a temperature of a stage on which the stacked film is placed is 70° C. or less.

18. The method of manufacturing the semiconductor memory device according to claim 13,
wherein the first film thickness is 0.3 nm or more and 10 nm or less, and the second film thickness is 25 nm or more and 45 nm or less.

19. The method of manufacturing the semiconductor memory device according to claim 13,
Wherein the third film thickness is 35% or more and 45% or less with respect to a total film thickness of the third film thickness and the fourth film thickness.

20. The method of manufacturing the semiconductor memory device according to claim 13, further comprising:
after forming the opening penetrating the stacked film and extending in the first direction and before the oxidation of the stacked film including the opening, forming a third layer containing a nitride on side surfaces of the first layers and side surfaces of the second layers exposed in the opening; and
when the oxidation of the stacked film including the opening is performed, oxidizing the third layer.
